(19) United States
(12) Patent Application Publication
(10) Pub. No.: US 2023/0420407 A1
(43) Pub. Date: Dec. 28, 2023

(54) PIN ARRAYING DEVICE, ARRAY FOR PIN ARRAYING, AND PIN ARRAYING METHOD

(71) Applicants: TOYAMA PREFECTURAL UNIVERSITY, Imizu-shi, Toyama (JP); FINECS CO., LTD., Funahashi-mura, Toyama (JP)

(72) Inventors: Isao SHIMOYAMA, Imizu-shi, Toyama (JP); Kentaro NODA, Imizu-shi, Toyama (JP); Takuya TSUKAGOSHI, Imizu-shi, Toyama (JP); Tsuyoshi MATSUI, Funahashi-mura, Toyama (JP); Sho TAKANAMI, Funahashi-mura, Toyama (JP); Ichiro KITAJIMA, Funahashi-mura, Toyama (JP)

(21) Appl. No.: 18/030,018

(22) PCT Filed: Sep. 30, 2021
(86) PCT No.: PCT/JP2021/036133

§ 371 Date: Sep. 8, 2023

(30) Foreign Application Priority Data
Oct. 6, 2020 (JP) 2020-169456

(51) Int. Cl. H01L 23/00

(52) U.S. Cl. CPC H01L 24/75; H01L 2224/75621; H01L 2224/75734

(57) ABSTRACT

A pin arrangement device includes: a storage portion in which a pin arrangement array body having a plurality of holes is disposed; and a mechanism for inserting pins into the holes of the pin arrangement array body disposed in the storage portion. The mechanism includes a first mechanism that vibrates the storage portion and a second mechanism that applies a magnetic field to the pin arrangement array body, and the first mechanism includes a swing mechanism that swings the storage portion and a vibration mechanism that vibrates the storage portion in a vertical direction or a horizontal direction.

### TECHNICAL FIELD

The present invention relates to a pin arrangement device, a pin arrangement array body, and a pin arrangement method.

### BACKGROUND ART

As a technique of laminated wiring, 3D wiring, and the like, there has been studied chiplet by which chips are integrated by a plurality of dies. In order to place and wire a die on another die, pins are required. The diameter and length of the pins are of the micro-order of 0.3 mm or less, for example.

### SUMMARY OF THE INVENTION

### Technical Problem

Since the size of the pins is very small, it is difficult to erect the lying pins or erect and arrange one or a plurality of pins in the chip manufacturing process.

Therefore, an object of the present invention is to provide a pin arrangement device, a pin arrangement array body, and a pin arrangement method for arranging pins upright.

### Solution to Problem

The concepts of the present invention are as follows.
[1] A pin arrangement device including:
a storage portion in which a pin arrangement array body having a plurality of holes is disposed; and
a mechanism for inserting pins into the holes of the pin arrangement array body disposed in the storage portion, wherein
the mechanism includes at least one of a first mechanism that vibrates the storage portion and a second mechanism that applies a magnetic field to the pin arrangement array body.
[2] The pin arrangement device further includes a third mechanism that communicates with the holes of the pin arrangement array body disposed in the storage portion and sucks the holes.
[3] In the pin arrangement device, the first mechanism includes any one or both of a swing mechanism that swings the storage portion and a vibration mechanism that vibrates the storage portion in a vertical direction or a horizontal direction.
[4] In the pin arrangement device, the second mechanism includes any one or a combination of a permanent magnet, an electromagnet, and a magnetic body.
[5] The pin arrangement device further includes a removal mechanism for removing the pin arrangement array body from the storage portion.
[6] The pin arrangement device further includes an inspection unit configured to inspect a ratio of insertion of pins into the holes of the pin arrangement array body.
[7] In the pin arrangement device, the inspection unit includes one or both of:
a first inspection unit that has an imaging unit that images a surface of the pin arrangement array body in which the pins are inserted into the holes, and a calculation unit that processes image data captured by the imaging unit and calculates the ratio; and
a second inspection unit that performs electrical measurement on the pin arrangement array body in which the pins are inserted into the holes, and calculates the ratio from electrical parameters including conductivity and dielectric constant.
[8] A pin arrangement array body including:
a plurality of holes, wherein
each of the holes has a hole diameter and a hole length of micro sizes corresponding to a diameter and a length of a pin to be arranged.
[9] In the pin arrangement array body, each of the holes is expanded.
[10] The pin arrangement array body further includes a guide along the adjacent holes.
[11] In the pin arrangement array body, depths of the holes vary depending on positions where the holes are provided.
[12] In the pin arrangement array body, the pin arrangement array body constitutes a part of a substrate on which a plurality of electronic devices is mounted.
[13] A pin arrangement method including: arranging a plurality of pins having a diameter and a length of micro sizes on a pin arrangement array body having holes of a diameter and a length corresponding to the diameter and length of the pins; and inserting the pins into the holes of the pin arrangement array body by vibrating the pin arrangement array body.
[14] A pin arrangement method including:
arranging a plurality of pins having a diameter and a length of micro sizes and responsive to a magnetic field on a pin arrangement array body having holes of a diameter and a length corresponding to the diameter and length of the pins; and
inserting the pins into the holes of the pin arrangement array body by applying a magnetic field to the pin arrangement array body.

### Advantageous Effects of the Invention

According to the present invention, pins can be efficiently arranged upright.

### BRIEF DESCRIPTION OF DRAWINGS

FIG. 1 A schematic view of a pin arrangement device and a pin arrangement array body according to a first embodiment of the present invention.

FIG. 2A A view schematically illustrating a state in which pins are inserted into holes by a pin arrangement device and a pin arrangement array body according to a second embodiment of the present invention, where the pins lie on the pin arrangement array body.

FIG. 2B A view schematically illustrating a state in which pins are inserted into holes by the pin arrangement device and the pin arrangement array body according to the second embodiment of the present invention, where a magnetic body is brought close to the pin arrangement array body from the underside.

FIG. 2C A view schematically illustrating a state in which pins are inserted into holes by the pin arrangement device and the pin arrangement array body according to the second embodiment of the present invention, where the magnetic body is brought further close to the pin arrangement array body from the underside.

FIG. 2D A view schematically illustrating a state in which pins are inserted into holes by the pin arrangement device and the pin arrangement array body according to the second embodiment of the present invention, where the magnetic body is closest to the pin arrangement array body.

FIG. 3 A schematic front view of a pin arrangement device and a pin arrangement array body according to a third embodiment of the present invention.

FIG. 4 A schematic plan view of the pin arrangement device and the pin arrangement array body according to the third embodiment of the present invention.

FIG. 5 A diagram schematically illustrating a pin arrangement device according to a fourth embodiment of the present invention.

FIG. 6 A plan view illustrating an example of the pin arrangement array body illustrated in FIG. 5.

FIG. 7A A cross-sectional view of a pin arrangement array body.

FIG. 7B A cross-sectional view of another pin arrangement array body.

FIG. 7C A cross-sectional view of another pin arrangement array body.

FIG. 7D A cross-sectional view of another pin arrangement array body.

FIG. 7E A cross-sectional view of another pin arrangement array body.

FIG. 8 A plan view of a housing case.

FIG. 9 A cross-sectional view of the housing case.

FIG. 10 An example of a time chart of swing and lateral vibration.

FIG. 11 A diagram schematically illustrating states of swing and lateral vibration.

FIG. 12 A diagram schematically illustrating a pin arrangement device according to a fifth embodiment of the present invention.

FIG. 13 A diagram schematically illustrating a method of removing the pin arrangement array body.

FIG. 14 A diagram illustrating a modification of the pin arrangement array body.

FIG. 15 A configuration diagram of a pin arrangement system according to an embodiment of the present invention.

### DESCRIPTION OF EMBODIMENTS

Hereinafter, embodiments of the present invention will be described in detail with reference to the drawings. The drawings illustrate one of preferred embodiments of the present invention. Modifications with partial deletions or additions of the components of the present invention are also included in the scope of the present invention without departing from the spirit of the present invention.

### First Embodiment

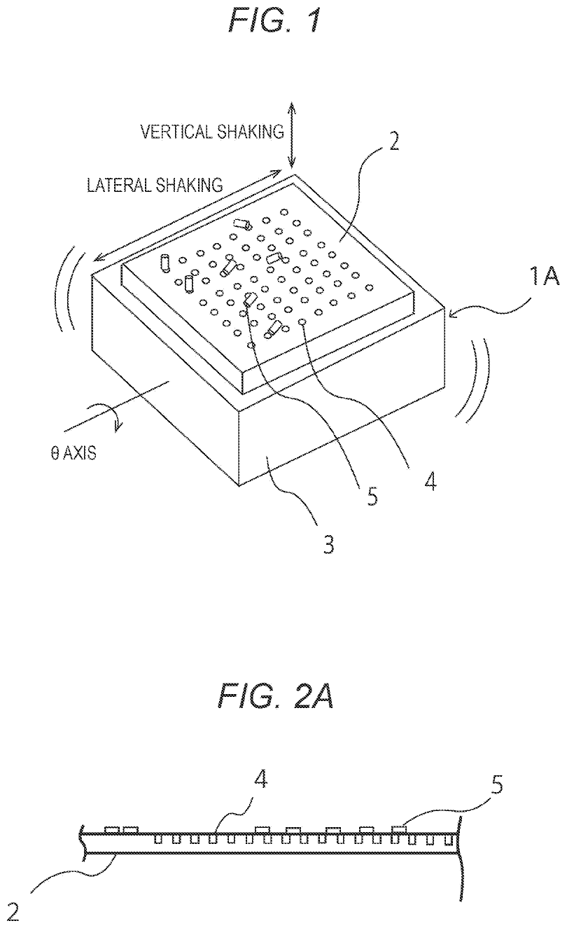

FIG. 1 is a schematic view of a pin arrangement device and a pin arrangement array body according to a first embodiment of the present invention. A pin arrangement device 1A according to a first embodiment of the present invention includes a vibration application unit 3 in which a pin arrangement array body 2 is disposed. As illustrated in FIG. 1, the vibration application unit 3 applies lateral vibration and/or vertical vibration to the pin arrangement array body 2 while swinging around a θ axis that is a swing axis. The lateral vibration means reciprocating vibration in a direction parallel to the upper surface of the pin arrangement array body 2, and the vertical vibration means reciprocating vibration in a direction perpendicular to the upper surface of the pin arrangement array body 2. The direction of the lateral vibration may be a direction parallel to the θ axis, a direction perpendicular to the θ axis, or a direction intersecting the θ axis (for example, a direction intersecting the 0 axis at 45 degrees) in a planar shape parallel to the pin arrangement array body 2.

The pin arrangement array body 2 is provided with a plurality of holes 4 arranged in the vertical direction and the lateral direction. The pin arrangement array body 2 may have holes 4 of the same depth or holes 4 of different depths according to the positions of the holes 4. The holes 4 may be either penetrating or non-penetrating. The holes 4 have a hole diameter and a length of micro sizes corresponding to the diameter and length of pins 5 to be arranged. The micro size is assumed to be a size of 1 μm or more and 1000 μm or less. The pins 5 have a cylindrical shape and have a diameter of 1 μm or more and 1000 μm or less and a length of 1 μm or more and 1000 μm or less, for example. Therefore, the holes 4 have a diameter 1.02 to 1.3 times the diameter of the pins 5. The holes 4 have a depth of 0.1 times or more and 5 times or less the length of the pins 5. This is because if the holes 4 are in these ranges with respect to the dimensions of the pins 5, one pin 5 can be inserted into one hole 4, and the pin 5 is unlikely to come out of the hole 4. The holes 4 may be provided perpendicularly to the upper and lower surfaces of the pin arrangement array body 2 or may be inclined with respect to the upper and lower surfaces of the pin arrangement array body 2. It is not required to provide the holes 4 having the same or similar shape and dimensions (in particular, depth) in one pin arrangement array body 2. Holes different in shape and dimensions may be provided in each place.

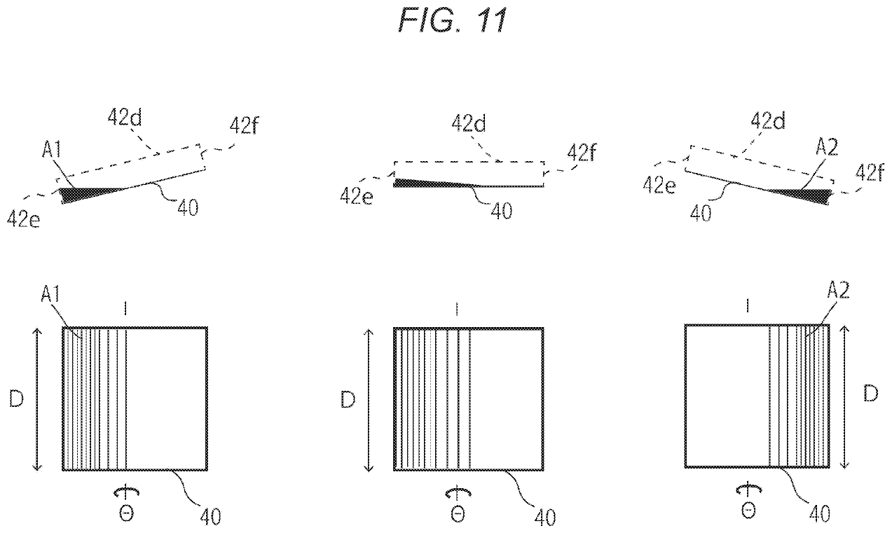

According to the pin arrangement device 1A illustrated in FIG. 1, the pin arrangement array body 2 is vertically and/or laterally shaken while being swung by the vibration application unit 3. The lateral shaking may be parallel or orthogonal to the swing axis that is the θ axis (also referred to as rotation axis) as illustrated in FIG. 1. A large number of pins 5 are placed on the pin arrangement array body 2, and are preferably scattered and spread widely in the width direction. The substantially horizontal pin arrangement array body 2 is rotated at an angle less than 90° about the swing axis (θ axis), and is stopped with the inclination maintained. The large number of pins 5 are collected on one end side of the pin arrangement array body 2. At that time, the large number of pins 5 have a substantially triangular cross section at one end portion of the pin arrangement array body 2 and spread between both ends (see detailed description of FIG. 11 to be described later). After such a state is maintained for a certain period of time, the pin arrangement array body 2 is rotated reversely about the θ axis and is vibrated laterally or vertically. Then, while the large number of pins 5 placed on the pin arrangement array body 2 are slid on the upper surface of the pin arrangement array body 2, some of the pins 5 are inserted into the holes 4, and the remaining pins 5 move and flow to the other end portion (the end portion opposite to the one end portion) of the pin arrangement array body 2. In this manner, the swinging and the temporary stoppage of the rotation of the pin arrangement array body 2 resulting from the forward rotation and reverse rotation at less than 90° mainly contribute to spreading the large number of pins 5 in the width direction to the one end portion and the other end portion of the pin arrangement array body 2, and the vertical vibration and/or the lateral vibration of the pin arrangement array body 2 mainly contribute to inserting one pin 5 into one hole 4. The swing cycle is about several seconds and 10 seconds or less, whereas the frequency of the vertical shaking and/or the lateral shaking is several tens of Hz such as 60 Hz, for example.

In this manner, the plurality of pins 5 having diameter and length of micro sizes are arranged on the pin arrangement array body 2 that has the holes 4 having diameter and length corresponding to the diameter and length of the pins 5. Then, the pin arrangement array body 2 is vibrated by the vibration application unit 3. As a result, the pins 5 are inserted into the holes 4 of the pin arrangement array body 2. Therefore, the plurality of pins 5 can be arranged in a predetermined positional relationship.

### Second Embodiment

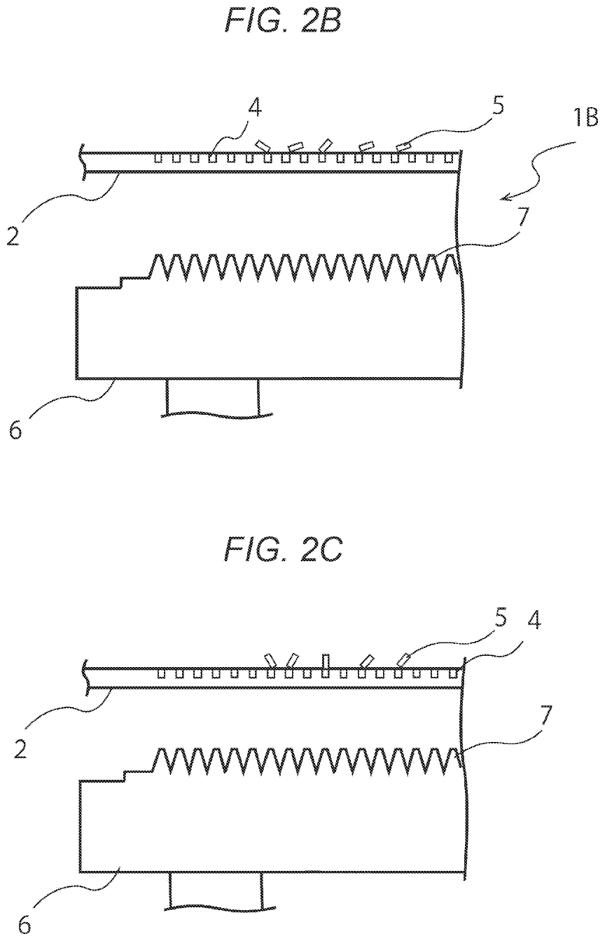

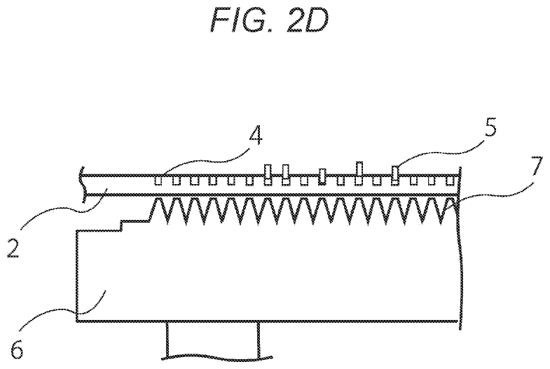

FIGS. 2A to 2D are diagrams schematically illustrating a state in which pins are inserted into holes by a pin arrangement device and a pin arrangement array body according to a second embodiment of the present invention. The right sides of the drawings are similar to the left sides, and thus illustration thereof is omitted. The drawings illustrate only some of the large number of pins 5.

A pin arrangement device 1B according to the second embodiment of the present invention is structured by providing a magnetic body 6 on a lower surface of a pin arrangement array body 2 so as to be vertically movable. The pins 5 are formed such that a force acts by a magnetic field. For example, the pins 5 may be similar to those of the first embodiment as long as at least the surfaces thereof are made of a magnetic material. This is because the pins 5 behave due to the magnetic field of the magnetic body 6. The pin arrangement array body 2 is the same as that of the first embodiment. The magnetic body 6 is preferably provided with a plurality of protrusions 7 so as to overlap with the holes 4 provided in the pin arrangement array body 2 in plan view. This is because a magnetic field is generated along the holes 4 to guide the pins 5 to the holes 4. The direction of the magnetic field does not need to be along the penetrating direction of the holes 4, and may be a direction intersecting the penetrating direction of the holes 4 in the cross sections illustrated in FIGS. 2A to 2D (for example, an orthogonal direction). Alternatively, the magnetic field may have components of these directions. The shape of the protrusions 7 is selected from a quadrangular pyramid shape, a conical shape, and the like, for example. The positions of the holes 4 of the pin arrangement array body 2 and the positions of the protrusions 7 may not overlap with each other in plan view. In such a case, for example, the magnetic body 6 having the protrusions 7 arranged at equal intervals vertically and horizontally may be moved in the side-to-side direction and the front-back direction.

According to the pin arrangement device 1B, when the magnetic body 6 is disposed below the pin arrangement array body 2, the pins 5 lie down on the surface of the pin arrangement array body 2 as illustrated in FIG. 2A. As the magnetic body 6 approaches the pin arrangement array body 2, the pins 5 rise toward the holes 4 and enter the holes 4 by themselves as illustrated in the order of FIGS. 2B to 2D.

As long as a magnetic field can be generated along the holes 4 of the pin arrangement array body 2, a plurality of electromagnets, instead of the magnetic body 6, may be disposed vertically and laterally on the lower side of the pin arrangement array body 2. At the insertion of the pins 5 into the holes 4 by the magnetic field, it is preferable to provide a positioning means like an XY stage for positioning.

In this manner, the plurality of pins 5 having a diameter and length of micro sizes and configured to receive the force of a magnetic field are arranged on the pin arrangement array body 2 that has the holes 4 having diameter and length corresponding to the diameter and length of the pins 5. Then, a magnetic field is applied to a region where the holes 4 of the pin arrangement array body 2 are provided. As a result, the pins 5 are inserted into the holes 4 of the pin arrangement array body 2. Depending on the positions of the holes 4, the depth of the holes 4, and the interval between the holes 4, a magnetic field may be obliquely generated so as to have not only a component of the vertical direction but also a component of the horizontal direction in the pin arrangement array body 2. The magnetic body 6 may be disposed so as not to generate a magnetic field in the central portion of the pin arrangement array body 2, but so as to generate a magnetic field only in a region away from the center of the pin arrangement array body 2 by a certain distance, a band-like region, for example, or an annular region, for example. In these cases, a plurality of magnetic bodies may be disposed such that the direction of the magnetic field has any one or both of a vertical component and a horizontal component with respect to the pin arrangement array body 2, and further has a component orthogonal to these two components.

### Third Embodiment

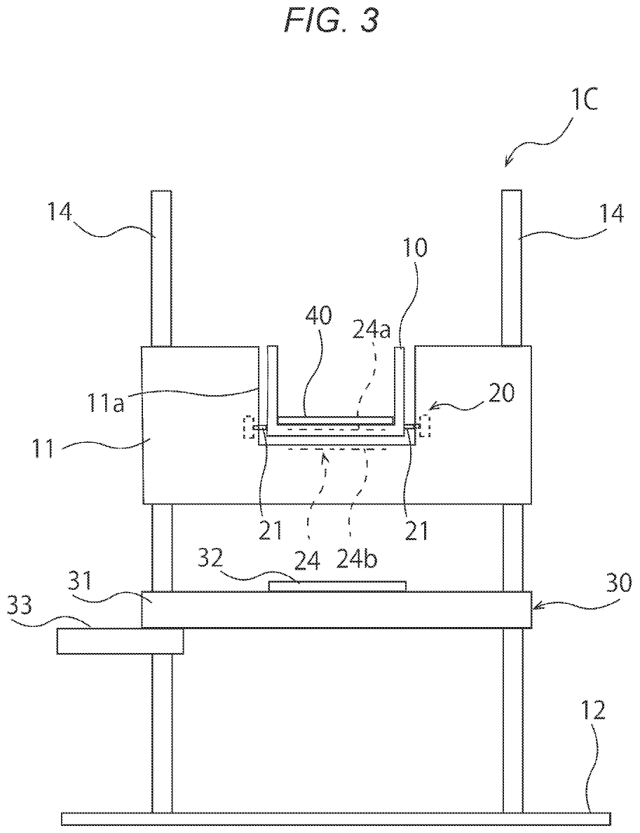

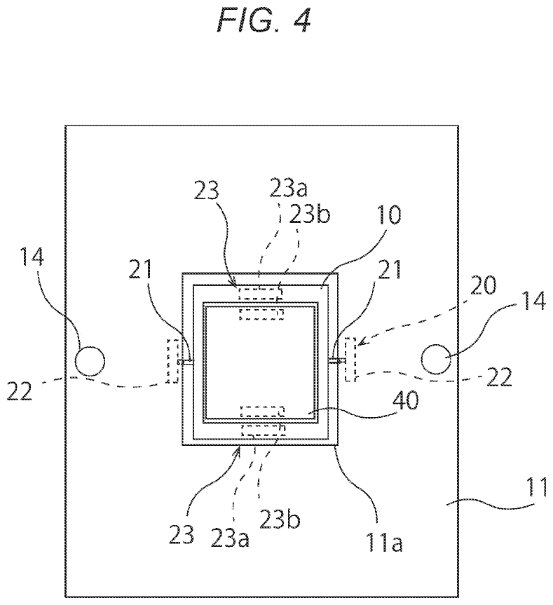

FIG. 3 is a schematic front view of a pin arrangement device and a pin arrangement array body according to a third embodiment of the present invention, and FIG. 4 is a schematic plan view of the pin arrangement device and the pin arrangement array body according to the third embodiment of the present invention.

A pin arrangement device 1C according to the third embodiment of the present invention includes a storage portion 10, and a first mechanism 20 and a second mechanism 30 as mechanisms for inserting pins. In the storage portion 10, a pin arrangement array body 40 having a plurality of holes is disposed. Both the first mechanism 20 and the second mechanism 30 are mechanisms for inserting pins into the holes of the pin arrangement array body 40, and any one or both of the mechanisms are provided in the pin arrangement device 1C. Since the pin arrangement array body 40 is similar to the pin arrangement array body 2 illustrated in FIGS. 1 and 2, details of the holes and the like are not illustrated.

The first mechanism 20 is intended to vibrate the storage portion 10. The “vibration” here includes not only any of vibration in the horizontal direction along the surface of the pin arrangement array body 40 (also referred to as “lateral vibration”) and vibration in a direction perpendicular to the surface of the pin arrangement array body 40 (also referred to as “vertical vibration”) but also both of them. The “vibration” further includes “swing” in which the time of one cycle including forward rotation, reverse rotation, and a stop therebetween constituting the “swing” is longer than the cycles of the lateral vibration and vertical vibration. Hereinafter, a configuration supporting all lateral vibration, vertical vibration, and swing will be described, and only a necessary mechanism may be selected.

The storage portion 10 has a recess formed so as to store the pin arrangement array body 40, and the longitudinal and lateral dimensions of the recess are slightly longer than the longitudinal and lateral dimensions of the pin arrangement array body 40. The storage portion 10 is supported on a support plate 11 by a shaft 21. The support plate 11 is supported substantially horizontally by a plurality of support columns 14 erected on a base 12 in a vertically movable manner, for example. A recess 11a is provided in a substantially central portion of the support plate 11 in plan view. The storage portion 10 having an open upper surface is disposed in the recess 11a. The storage portion 10 is provided with walls on the right, left, front, and rear.

The first mechanism 20 includes a swing mechanism 22 that is supported on the support plate 11 by the shaft 21 to swing the storage portion 10, a lateral shaking mechanism 23 that laterally shakes the storage portion 10, and a vertical shaking mechanism 24 that vertically shakes the storage portion 10. The lateral shaking mechanism 23 and the vertical shaking mechanism 24 are driven by electrostatic force resulting from electrodes 23a and 24a arranged in the storage portion 10 and electrodes 23b and 24b arranged on the support plate 11 so as to face the electrodes 23a and 24a. Instead of the electrostatic force, any one or a combination of a permanent magnet, a magnetic circuit, and an electromagnet may be driven by a magnetic force. The electrodes 23a and 23b are shown only in FIG. 4 and are omitted in FIG. 3. The electrodes 24a and 24b are shown only in FIG. 3 and are omitted in FIG. 4. In addition, wiring lines and the like connected to the electrodes 23a, 23b, 24a, and 24b are also omitted in the drawing.

Since the storage portion 10 is swung by the swing mechanism 22 and is laterally shaken and/or vertically shaken by either or both of the lateral shaking mechanism 23 and the vertical shaking mechanism 24, any one of the right, left, front, and rear walls of the storage portion 10 serves as a guide, and the pins are collected by the swing and are inserted into the holes by the vertical shaking and the lateral shaking. This will be described in detail with reference to FIG. 11.

The second mechanism 30 is a mechanism that applies a magnetic field to the pin arrangement array body 40 disposed in the storage portion 10. As illustrated in FIG. 3, a plate 31 on which a magnetic body 32 is placed is provided below the storage portion 10. For example, the plate 31 is vertically movably supported by the plurality of support columns 14. A stop bar 33 engages with one support column 14 under the plate 31 to stop the vertical movement of the plate 31. The magnetic body 32 is preferably provided with a plurality of protrusions 7 so as to overlap with the holes 4 provided in the pin arrangement array body 2 in plan view as described with reference to FIG. 2. This is because a magnetic field is generated along the axial direction of the holes 4, and the magnetic field guides the pins 5.

As far as the second mechanism 30 can generate a magnetic field in the pin arrangement array body 40, the second mechanism 30 is not only configured to bring the plate 31 on which the magnetic body 32 is placed close to the support plate 11 from the lower side as illustrated in FIG. 3, but also may have a plurality of electromagnets disposed side by side in the side-to-side direction and the front-rear direction under the support plate 11, for example. A plurality of electromagnets may be incorporated in the surface of the storage portion 10 on which the pin arrangement array body 40 is placed.

As a third mechanism, there is included a unit that communicates with the holes of the pin arrangement array body 40 arranged in the storage portion 10 and sucks the holes. This is implemented by sucking by a vacuum (not illustrated) serving as a suction unit coupled to the support plate 11. The holes of the pin arrangement array body 40 penetrate, and the diameter of the holes on the side opposite to the insertion side of the pins is shorter than the diameter of the holes on the insertion side. This is to prevent the pins from coming out of the holes 41. When the third mechanism is used in combination with the first mechanism, the pins are efficiently inserted into the holes of the pin arrangement array body 40.

### Fourth Embodiment

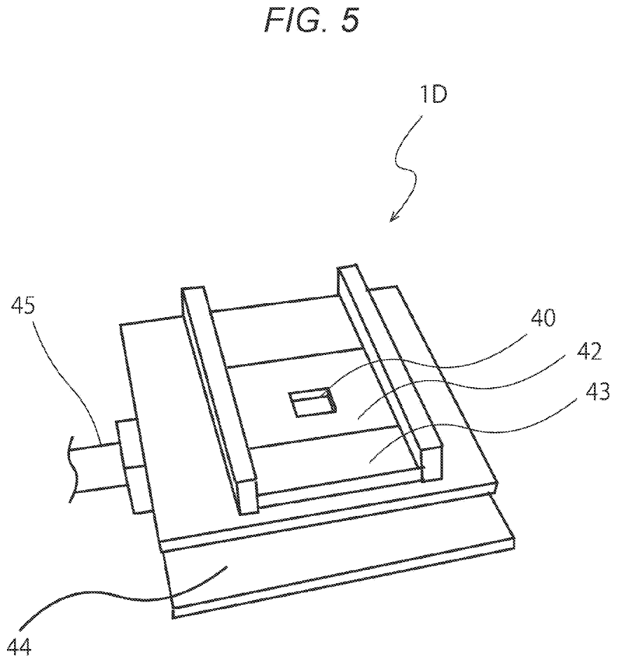

FIG. 5 is a diagram schematically illustrating a pin arrangement device according to a fourth embodiment of the present invention. As illustrated in FIG. 5, a pin arrangement device 1D according to the fourth embodiment of the present invention includes a housing case 42 on which a pin arrangement array body 40 is placed, a holding portion 43 that holds the housing case 42, a vibration application unit 44 that applies lateral vibration and swing to the holding portion 43 together with the housing case 42, and a suction unit that sucks a region defined by being connected to the housing case 42. The housing case 42 corresponds to the storage portion in the third embodiment.

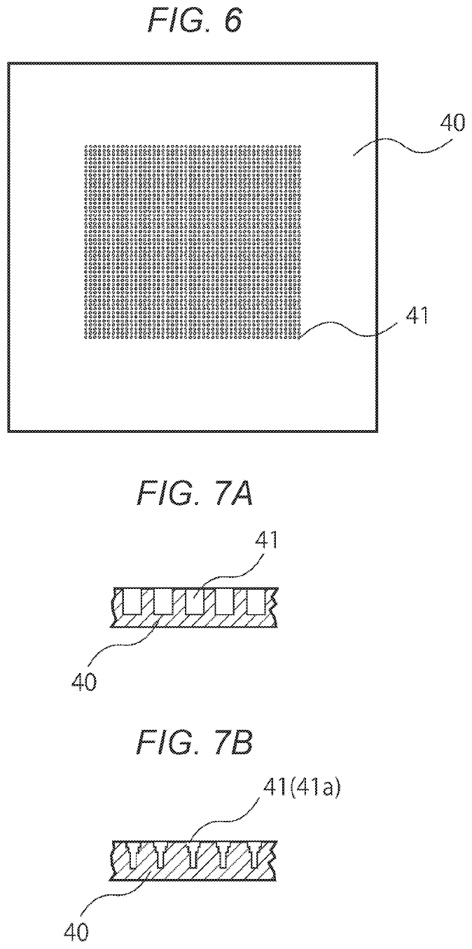

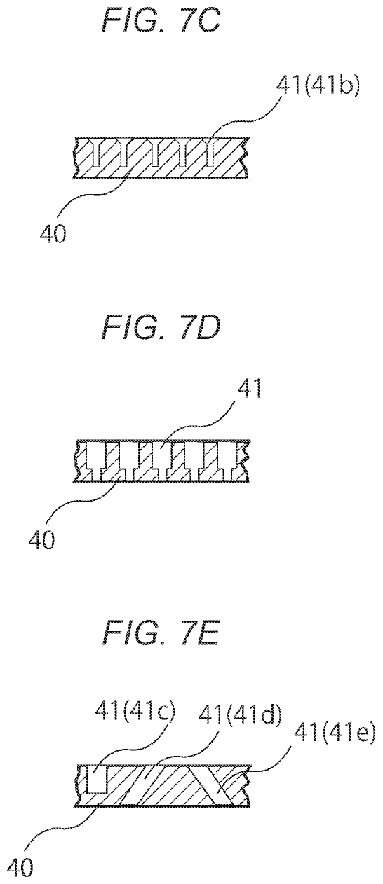

FIG. 6 is a plan view of an example of the pin arrangement array body 40 shown in FIG. 5, and FIGS. 7A to 7D are diagrams showing cross-sectional views of the pin arrangement array body 40. The pin arrangement array body 40 includes a semiconductor substrate such as Si, and is manufactured by a semiconductor process such as photolithography and etching, for example. The pin arrangement array body 40 is provided with a plurality of holes 41 along a predetermined arrangement pattern, and each of the holes 41 has a hole diameter and a length of micro sizes corresponding to the diameter and length of the pins to be arranged, as in the case described above. The shape of the holes 41 may be different depending on the arrangement position. The holes 41 may intersect with the upper surface of the pin arrangement array body 40, including perpendicular thereto.

In the pin arrangement array body 40, as illustrated in FIGS. 7B and 7C, it is preferable that the holes have a larger diameter at the portion close to the front surface than other portions and are expanded. This is intended to make the pins easy to enter the hole 41 and hard to remove from the holes 41. As for the mode of expansion, the holes may be stepped holes 41a as shown in FIG. 7B that are the same in diameter with respect to the depth direction and are reduced in diameter with increase in depth, or may be tapered holes 41b as shown in FIG. 7C.

If the holes 41 are through holes 41 as illustrated in FIG. 7D, the holes 41 satisfies the condition for non-through holes and also have the diameter shorter on the side opposite to the insertion side of the pins than on the insertion side. This is to prevent the pins from coming out of the holes 41. As illustrated in FIG. 7E, the holes 41 may be different in depth or in the shape of a cross section in one pin arrangement array body 40. For example, as illustrated in FIG. 7E, the holes may be non-through holes 41c or inclined holes 41d and 41e.

The pin arrangement array body 40 has a size of 1 inch square, for example, and has a thickness of 0.5 mm, for example. The surface of the pin arrangement array body 40 is satin finish. The pin arrangement array body 40 preferably has surface roughness. The surface roughness is around Ra 4.5 μm, for example. This is to prevent the pins from lying on the surface of the pin arrangement array body 40 and adhering to the surface due to static electricity.

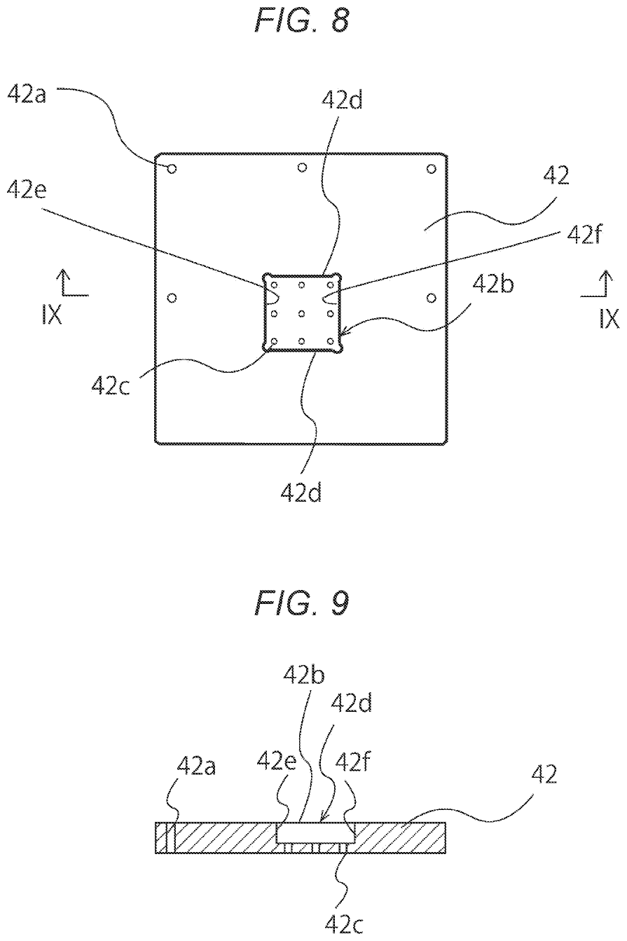

FIG. 8 is a plan view of the housing case, and FIG. 9 is a cross-sectional view of the housing case. The housing case 42 has a plurality of fixing holes 42a in the periphery, and has a recess 42b that is rectangular in plan view at the center. Through holes 42c are provided at the bottom of the recess 42b. The pin arrangement array body 40 illustrated in FIG. 6 is inserted into the recess 42b of the housing case 42. The recess 42b of the housing case 42 has such a dimensional shape that the pins arranged on the upper surface of the pin arrangement array body 40 do not enter the gap between the housing case 42 and the pin arrangement array body 40. The housing case 42 holds the pin arrangement array body 40, and therefore is preferably made of a conductive material. From the viewpoint of light weight and abrasion resistance, it is preferable to use a polyphenylene sulfide resin or a resin having properties similar to those of the polyphenylene sulfide resin.

Next, a method for inserting and arranging pins into the holes 41 of the pin arrangement array body 40 using the pin arrangement device 1D will be described.

First, the pin arrangement array body 40 is disposed in the recess 42b of the housing case 42. An appropriate quantity of pins are placed on the upper surface of the pin arrangement array body 40. The appropriate quantity is larger than the number of holes 41 of the pin arrangement array body 40. A spoon is used to measure an appropriate quantity of pins. The appropriate quantity depends on the combination of swing constituting vibration, vertical vibration, and lateral vibration, and specific conditions thereof.

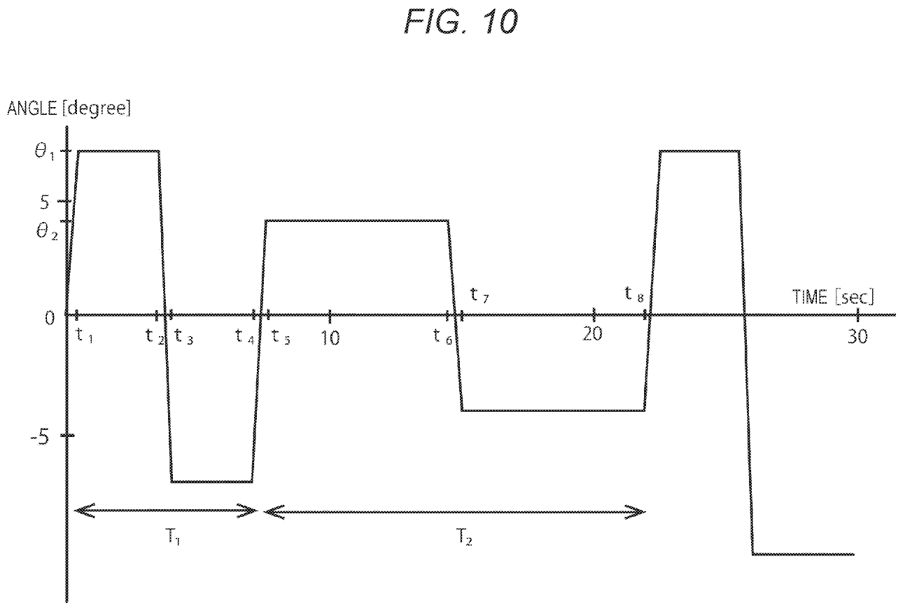

Next, the pin arrangement array body 40 is laterally shaken while being swung around the swing axis (θ axis) while the lower side of the pin arrangement array body 40 is brought under a negative pressure by the suction unit connected to the suction pipe 45. FIG. 10 illustrates an example of a time chart of swing and lateral vibration, where the horizontal axis represents time (seconds) and the vertical axis represents the angle of rotation (°). The frequency of the lateral shaking is 60 Hz, for example, whereas the cycle of the lateral shaking is two seconds, three seconds or more and about seven seconds, and within ten and several seconds.

FIG. 11 illustrates a state in which the pin arrangement array body 40 is swung and laterally vibrated according to the time chart of FIG. 10, where the number of pins is conceptually shown in accordance with the arrangement of the pins in the order of positive, zero, and negative rotation angles around the swing axis from left to right. In this case, the specific numerical values in FIG. 10 are examples, and do not specify the embodiment.

At the starting stage (t=0), the pin arrangement array body 40 is horizontal, for example, and a large number of pins are placed on the upper surface of the pin arrangement array body 40. At that time, it is preferable that the pins are evenly placed across the surface. For the sake of explanation, at the start stage, the pin arrangement array body 40 is substantially horizontal, but may be inclined with a rotation at either a positive or negative rotation angle around the swing axis.

Then, in a time slot (0<t≤t₁) in which the rotation angle around the swing axis increases from zero to a certain positive value (θ₁), a large number of pins are sliding down the inclined surface while the inclination angle of the pin arrangement array body 40 increases from the horizontal. At that time, some of the large number of pins are inserted into the holes by the lateral vibration to the pin arrangement array body 40.

When the rotation angle around the swing axis reaches the certain positive value θ₁, the rotation of the pin arrangement array body 40 is stopped while the pin arrangement array body 40 is inclined. In a time slot during which the rotation is stopped (t₁≤t≤t₂), as schematically illustrated in a cross-sectional view and a plan view in the upper and lower left parts of FIG. 11, the large number of pins are present in various orientations in a region A1 extending in a width D direction and having a triangular shape in cross section shown by the inclined pin arrangement array body 40 and one end portion 42e of the recess 42b. The mesh in the plan view correspond to the magnitude of the number of pins. The large number of pins spread over the full width D with the guide side surface portion 42d at both ends. The lateral vibration spreads the pins across the full width D.

Then, in a time slot (t₂≤t≤t₃) in which the rotation angle around the swing axis decreases from the certain positive value θ₁ to a certain negative value (−θ₁), the pin arrangement array body 40 is oriented in the opposite direction as if warping the palm and increases in the inclination angle, and the large number of pins are sliding down the inclined surface. In the middle, that is, in a state where the pin arrangement array body 40 is substantially horizontal, the large number of pins hardly move on the upper surface of the pin arrangement array body 40 as illustrated schematically in an upper cross-sectional view and a lower plan view in the middle of FIG. 11. This is because a large force to move to the other end portion 42f of the recess 42b does not act on the pins. Then, as the rotation angle reaches the certain negative value (−θ₁), the inclination of the pin arrangement array body 40 is reversed. Thus, a force to move to the other end portion 42f of the recess 42b starts to act on the large number of pins, and the large number of pins are sliding down so as to flow on the inclined surface. At this time, some of the large number of pins are inserted into the holes due to the lateral vibration to the pin arrangement array body 40.

When the rotation angle reaches −θ₁, the rotation of the pin arrangement array body 40 is stopped while the pin arrangement array body 40 is inclined. A large force to move to the other end portion 42f of the recess 42b acts on the pins. In a time slot during which the rotation is stopped (t₃≤t≤t₄), as illustrated in a plan view and a cross-sectional view in the upper and lower right parts of FIG. 11, the large number of pins are present in various orientations in a region A2 extending in the width direction and having a triangular shape in cross section shown by the inclined pin arrangement array body 40 and the other end portion 42f of the recess 42b. The number of meshes in the plan view corresponds to the magnitude of the number of pins. The large number of pins spread over the full width D with the guide side surface portion 42d at both ends.

Then, in a time slot (t₄≤t≤t₅) in which the rotation angle increases from the certain negative value (−θ₁) to a certain positive value (θ₂), the pin arrangement array body 40 returns its inclination in the original direction, and the large number of pins tend to slide down the inclined surface. In the middle, that is, when the pin arrangement array body 40 becomes substantially horizontal, the large number of pins hardly move on the upper surface of the pin arrangement array body 40. This is because a large force to move to the one end portion 42e of the recess 42b does not act on the pins. At this time, the number of meshes is horizontally reversed from the case illustrated in the middle of FIG. 11. Then, as the rotation angle comes closer to the certain positive value (θ₂), the inclination of the pin arrangement array body 40 is reversed, so that the large number of pins tend to slide down so as to flow on the inclined surface. The subsequent process is redundant, and thus description thereof will be omitted.

As described above, the time chart includes a plurality of terms such as a first term T₁ during which the pin arrangement array body 40 is inclined as the rotation angle changes from zero to θ₁ and then the rotation angle changes from θ₁ through −θ₁ to zero, and a subsequent second term T₂ during which the pin arrangement array body 40 is inclined as the rotation angle increases from zero to θ₂ and then the rotation angle changes from θ₂ through −θ₂ to zero. At the end of arrangement and insertion of the pins, the pin arrangement array body 40 may be horizontal or inclined.

The maximum rotation angle θ₂ in the second term T₂ may be the same as or different from the maximum rotation angle θ₁ in the first term T₁. The positive maximum inclination angle (for example, θ₁ in the first term) at each term does not necessarily need to coincide with the magnitude of the negative maximum inclination angle. However, it is preferable that the positive maximum inclination angle coincide with the negative maximum inclination angle for the sake of system control.

In the case illustrated in FIG. 11, the relationship of the maximum rotation angles θ₁≥θ₂ is satisfied, and the time (t₅≤t≤t₆) during which the pin arrangement array body 40 is maintained at the rotation angle θ₂ is longer than the time (t₁≤t≤t₂) during which the pin arrangement array body 40 is maintained at the rotation angle θ₁. This is because even if the inclination angle of the pin arrangement array body 40 is increased from zero and then the increase in the inclination angle is stopped, a large number of pins are still moving on the upper surface of the pin arrangement array body 40. Due to this time lag, when the rotation of the pin arrangement array body 40 is stopped while being inclined, the pins easily enter the holes by the action of the lateral vibration.

The period during which the inclination angle of the pin arrangement array body 40 is increased or decreased, that is, the period during which the inclination changes is shorter than the period during which the inclination is maintained and the rotation is temporarily stopped. The period during which the rotation of the pin arrangement array body 40 is temporarily stopped with an inclination differs for each term. The period of temporary stop of the rotation with a large inclination is shorter than the period of temporary stop of the rotation with a small inclination. This is because, during the period of temporary stop of the rotation with a large inclination, a large number of pins on the pin arrangement array body 40 are spread across the full width D in the specific regions A1 and A2, as illustrated in the left and right upper and lower parts of FIG. 11. This is also because the larger the inclination of the pin arrangement array body 40 is, the more quickly a large number of pins on the pin arrangement array body 40 can reach the specific regions A1 and A2.

This series of description is about a phenomenon due to swinging and lateral vibration. A similar phenomenon occurs in swinging and vertical vibration. Furthermore, if the lower side of the pin arrangement array body 40 is brought under a negative pressure by the suction unit connected to the suction pipe 45, the pins are more easily inserted into the holes.

In this manner, the large number of pins are placed on the pin arrangement array body 40, preferably, so as to spread evenly, and the pin arrangement array body 40 is inclined at less than 90° around the swing axis to collect the pins on the one end portion 42e side (region A1) of the pin arrangement array body 40. At this time, the large number of pins are widely present between both ends (that is, across the width D) with a substantially triangular cross section at the one end portion 42e of the pin arrangement array body 40. After such a state is maintained for a certain period of time, the pin arrangement array body 40 is reversely rotated around the swing axis to laterally vibrate or vertically vibrate. Accordingly, as the large number of pins slide on the upper surface of the pin arrangement array body 40, some of the pins are inserted into the holes, and the remaining pins move to the other end portion 42f (end portion opposite to the one end portion 42e, region A2) of the pin arrangement array body 40. In this manner, the swinging and the temporary stoppage of the rotation resulting from the forward rotation and reverse rotation at less than 90° mainly contribute to spreading the large number of pins in the width direction to the one end portion 42e and the other end portion 42f of the pin arrangement array body 40, and the vertical vibration and/or the lateral vibration mainly contribute to inserting one pin into one hole.

In this manner, according to the pin arrangement method, the plurality of pins having diameter and length of micro sizes are arranged on the pin arrangement array body 40 that has the holes having diameter and length corresponding to the diameter and length of the pins, and then the pin arrangement array body 40 is vibrated. Thus, the pins can be inserted into the corresponding holes of the pin arrangement array body 40.

### Fifth Embodiment

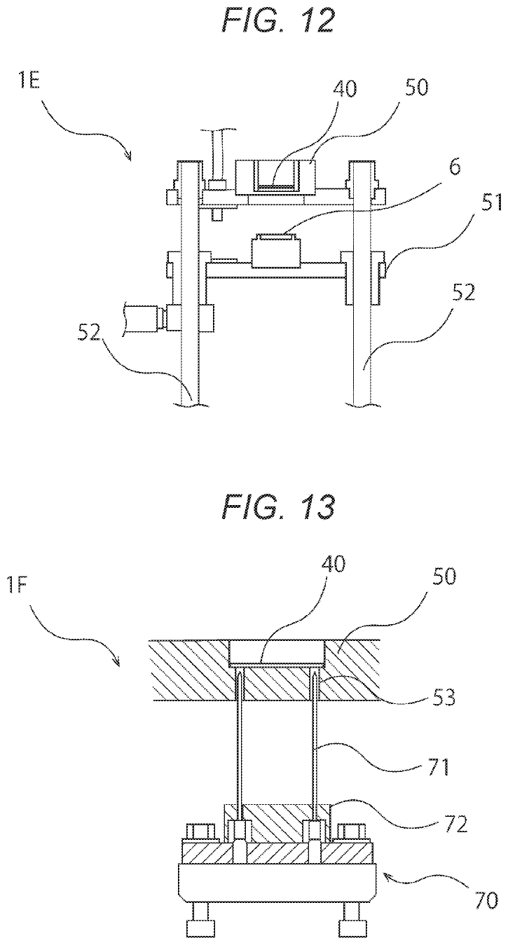

FIG. 12 is a diagram schematically illustrating a pin arrangement device according to a fifth embodiment of the present invention. As illustrated in FIG. 12, a pin arrangement device 1E according to the fifth embodiment of the present invention includes a storage portion 50 on which a pin arrangement array body 40 is placed, a magnetic body support portion 51 that is arranged below the storage portion 50 and moves up and down, and a plurality of support columns 52 that supports the storage portion 50 and the magnetic body support portion 51.

The plurality of support columns 52 is supported and erected by a base portion (not illustrated), the magnetic body support portion 51 is vertically movably supported by the support columns 52, and the storage portion 50 is supported by the support columns 52. The recess of the storage portion 50 in plan view has a gap of a predetermined dimension between the storage portion 50 and the pin arrangement array body 40 as in the fourth embodiment. The pin arrangement array body 40 is arranged in the storage portion 50, and an appropriate quantity of pins are placed on the pin arrangement array body 40. At this time, the pins lie on the pin arrangement array body 40.

The magnetic body support portion 51 is brought close to the lower side of the pin arrangement array body 40 with the storage portion 50 interposed therebetween. The magnetic body 6 supported by the magnetic body support portion 51 forms a magnetic field along the vertical direction, and accordingly, the pins react and behave as if the pins follow the magnetic field. Specifically, as a magnetic body 6 approaches the pins, the pins are raised toward the holes, and the raised pins enter the holes, as described above with reference to FIGS. 2A to 2D.

In this manner, according to the pin arrangement method, the plurality of pins having a diameter and length of micro sizes and responsive to a magnetic field are arranged on the pin arrangement array body that has the holes having diameter and length corresponding to the diameter and length of the pins. Next, a magnetic field is applied to the pin arrangement array body. Thus, the pins can be inserted into the holes of the pin arrangement array body.

### OTHER EMBODIMENTS

The pin arrangement array body 40 in which pins are inserted into the holes 41 is removed by various methods. FIG. 13 is a diagram schematically illustrating a method of removing the pin arrangement array body 40. As illustrated in FIG. 13, a removal mechanism 70 of the removal device 1F is placed under the storage portion 50. The removal mechanism 70 includes a plurality of rod members 71 to be inserted into the holes 53 penetrating the storage portion 50, a support portion 72 that supports the rod members 71, and a vertical movement mechanism (not illustrated) that vertically moves the support portion 72. The support portion 72 is moved up and down by the vertical movement mechanism, and the rod members 71 are inserted into the holes 53 to lift up the pin arrangement array body 40. This allows the pin arrangement array body 40 to be removed from the storage portion 50. The through holes 42c illustrated in FIG. 8 correspond to the holes 53 illustrated in FIG. 13. The pin arrangement array body 40 can be easily removed from the recess 42b of the housing case 42.

Conforming whether the pins are inserted into the holes will be described. Each of the pin arrangement devices 1A to 1E includes an inspection unit, and can inspect the ratio of insertion of the pins into the holes of the pin arrangement array bodies 2 and 40. A plurality of inspection units is conceivable. A first inspection unit includes an imaging unit that captures an image of the surface of the pin arrangement array body in which the pins are inserted into the holes, and a calculation unit that processes the image data captured by the imaging unit and calculates the ratio. Specifically, the first inspection unit captures an image of the surface of the pin arrangement array body by the imaging unit, and acquires the state in which the pins are inserted into the holes as image data. The calculation unit performs image processing such as patterning on portions of the pins in the image data, counts the number of shapes with a predetermined size, and calculates the ratio of the count to the total number of holes. As a result, the insertion ratio of the pins into the holes can be calculated, and the pass/fail can be determined.

In another aspect of the inspection unit, electrical measurement is performed on the pin arrangement array body in which the pins are inserted into the holes, so that the insertion ratio of the pins into the holes can be calculated from electrical parameters including the conductivity and the dielectric constant, and the pass/fail can be determined.

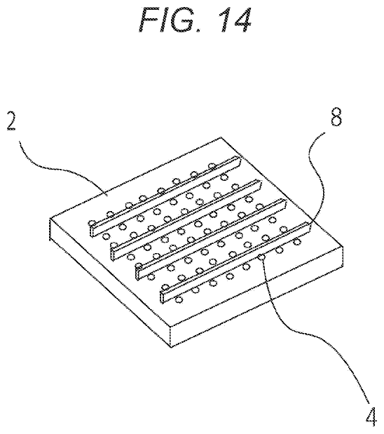

The embodiments of the present invention are not limited to the above-described embodiments and also include various modifications. For example, as illustrated in FIG. 14, guides 8 may be provided on the upper surface of the pin arrangement array body. The guides have a shape along the holes so as to connect the edges of the adjacent holes in one direction. The guide can be provided for each row as illustrated in FIG. 14, and the shape of the guides can be set by the direction of swing, the direction of vibration, or the like so that the pins are sequentially inserted into the plurality of holes.

The holes of the pin arrangement array body may be either through holes or non-through holes. In particular, if the pin arrangement array body constitutes a substrate (for example, a die) itself on which a plurality of electronic devices is mounted, the holes of the pin arrangement array body are preferably through holes. This is because wiring connection can be performed by vertically superposing such substrates and coupling the upper substrate and the lower substrate with pins.

In the embodiment of the present invention, the pin arrangement array is not only processed by a semiconductor process such as photolithography and etching on silicon wafer, but also used for preparing a TSV process. That is, the pin arrangement array is also used to insert pins serving as pillars into through holes of a DRAM chip.

In the embodiment of the present invention, the magnetic body 6 is preferably made of a ferromagnetic material. This is because the pins can be easily inserted into the holes by a magnetic field.

In the embodiment of the present invention, the surfaces of the pin arrangement array bodies 2 and 40 are preferably provided with hydrophilic and hydrophobic patterns. This is because the adhesive force of the pins to the pin arrangement array bodies 2 and 40 is controlled to separate a region where the pins are easily gathered and a region where the pins are not easily gathered. For example, in the case of pins having hydrophobicity, the pins are difficult to attach in a region having hydrophobicity, whereas the pins are easy to attach in a region having hydrophilicity. Therefore, it is possible to provide a function similar to that of the guides described above. In addition, the surfaces of the pin arrangement array bodies 2 and 40 are preferably conductive.

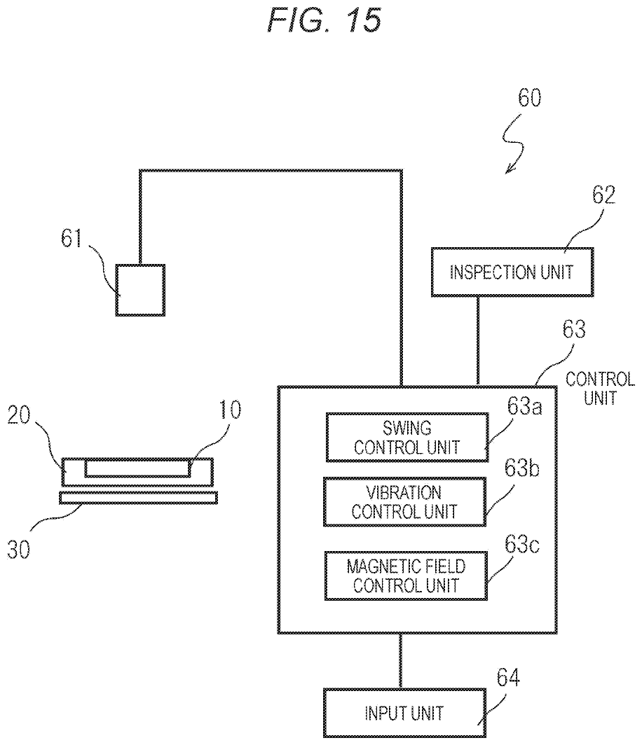

As an embodiment of the present invention, a pin arrangement system 60 will be described. FIG. 15 is a configuration diagram of the pin arrangement system according to the embodiment of the present invention. The pin arrangement system 60 includes a storage portion 10, a first mechanism 20, a second mechanism 30, and a control unit 63 for controlling the first mechanism 20 and the second mechanism 30. The storage portion 10, the first mechanism 20, and the second mechanism 30 have already been described. An imaging unit 61 is a camera that is disposed facing the storage portion 10 and captures an image of the pin arrangement array body. The control unit 63 includes a swing control unit 63a, a vibration control unit 63b, and a magnetic field control unit 63c. The swing control unit 63a controls the first mechanism 20 to control the swing of the storage portion 10. The vibration control unit 63b controls the first mechanism 20 to control lateral vibration and/or vertical vibration of the storage portion 10. The magnetic field control unit 63c adjusts the position of the second mechanism 30, for example, the magnetic body, controls the positional relationship with the permanent magnet, or electrically controls the electromagnet, thereby to control the presence or absence of application of a magnetic field to the pin arrangement array body in the storage portion 10 and the magnitude of the magnetic field. An inspection unit 62 acquires imaging data on the surface of the pin arrangement array body from the imaging unit 61, performs image processing such as patterning on pin portions of the data, counts the number of shapes of a predetermined size of the pins, and calculates the ratio of the count to the total number of holes. The results of calculation by the inspection unit 62 are fed back to the control of each unit by the control unit 63. An input unit 64 issues control instructions to the swing control unit 63a, the vibration control unit 63b, and the magnetic field control unit 63c, according to the status of visual inspection by the worker, not the results of imaging by the imaging unit 61.

The swing control unit 63a can adjust the swing pattern by changing the rotation angle of the swing shaft and the speed of the rotation angle, and the temporary stop time of the rotation for each term. In the vibration control unit 63b, the vibration pattern can be adjusted by changing the type of vertical shaking and lateral shaking, and the frequency of shaking. The magnetic field control unit 63c can change the magnetic field pattern by controlling the temporal position of the magnetic body and the temporal position of the permanent magnet, and electrically controlling the electromagnet. These parameters can be input to the control unit 63 by the input unit 64, or can be input to the control unit 63 as a parameter change command by the inspection unit 62. The worker may partially change the parameters without depending on such a system as described above.

Examples will be described. As Example 1, lateral vibration and swing were applied to a pin arrangement array body to insert pins into holes as described above in relation to the fourth embodiment. The first test by a detection unit has revealed that 1597 pins were inserted into 1600 holes. It took 36 seconds for the pins to be inserted into most of the holes. The hole diameter was 0.27 mm and the hole depth was 0.4 mm.

As Example 2, a permanent magnet was arranged at about 2 mm to 10 mm from a pin arrangement array body. At that time, the magnetic force was 4600 gauss to 4900 gauss. The orientation of the magnetic field was perpendicular and inclined with respect to the pin arrangement array body. The number of holes was 1600, the hole diameter was 0.27 mm, and the hole depth was 0.4 mm. As a result, it took 20 seconds for the pins to be inserted into most of the holes. It has been confirmed that the pins can be inserted into holes having a small diameter as compared with the case of using swing and vibration. The pins can be inserted with the gap (clearance) of 0.03 mm to 0.05 mm.

As Example 3, swing and vibration were applied to a pin arrangement array body under the same conditions as in Example 1, and a magnetic field was further applied to the pin arrangement array body under the same conditions as in Example 2. As a result, it took 10 seconds for the pins to be inserted into most of the holes. The time required was shorter than those in Examples 1 and 2. Accordingly, it has been confirmed that the influence of the magnetic field strongly acts, and the effect of superimposition of swing and vibration with the magnetic field can be obtained.

The distance between the pin arrangement array body and the magnet and the strength of the magnet (strength of the magnetic field) are set by the wire diameter and the length of the pin.

### REFERENCE SIGNS LIST

1A, 1B, 1C, 1D, 1E: Pin arrangement device
2: Pin arrangement array body
3: Vibration application unit
4: Hole
5: Pin
6: Magnetic body
7: Protrusion
8: Guide
10: Storage portion
11: Support plate
12: Base
14: Support column
20: First mechanism
21: Axis
22: Swing mechanism
23: Lateral shaking mechanism
24: Vertical shaking mechanism
23a, 23b, 24a, 24b: Electrode
30: Second mechanism
31: Plate
40: Pin arrangement array body
41, 41a, 41b: Hole
42: Housing case
43: Holding portion
44: Vibration application unit
45: Suction pipe
50: Storage portion
51: Magnetic body support portion
52: Support column
53: Hole
60: Pin arrangement system
61: Imaging unit
62: Inspection unit
63: Control unit
63a: Swing control unit
63b: Vibration control unit
63c: Magnetic field control unit
64: Input unit

1. A pin arrangement device comprising:
a storage portion in which a pin arrangement array body having a plurality of holes is disposed; and
a mechanism for inserting pins into the holes of the pin arrangement array body disposed in the storage portion, wherein
the mechanism includes a first mechanism that vibrates the storage portion and a second mechanism that applies a magnetic field to the pin arrangement array body, and
the first mechanism includes a swing mechanism that swings the storage portion and a vibration mechanism that vibrates the storage portion in a vertical direction or a horizontal direction.

2. The pin arrangement device according to claim 1, further comprising a third mechanism that communicates with the holes of the pin arrangement array body disposed in the storage portion and sucks the holes.

3. (canceled)

4. The pin arrangement device according to claim 1, wherein the second mechanism includes any one or a combination of a permanent magnet, an electromagnet, and a magnetic body.

5. The pin arrangement device according to claim 1, further comprising a removal mechanism for removing the pin arrangement array body from the storage portion.

6. The pin arrangement device according to claim 1, further comprising an inspection unit configured to inspect a ratio of insertion of pins into the holes of the pin arrangement array body.

7. The pin arrangement device according to claim 6, wherein the inspection unit includes one or both of:
a first inspection unit that has an imaging unit that images a surface of the pin arrangement array body in which the pins are inserted into the holes, and a calculation unit that processes image data captured by the imaging unit and calculates the ratio; and
a second inspection unit that performs electrical measurement on the pin arrangement array body in which the pins are inserted into the holes, and calculates the ratio from electrical parameters including conductivity and dielectric constant.

8. A pin arrangement array body for the pin arrangement device according to claim 1:
wherein
each of the holes has a hole diameter and a hole length of micro sizes corresponding to a diameter and a length of each of the pins to be arranged.

9. The pin arrangement array body according to claim 8, wherein each of the holes is expanded.

10. The pin arrangement array body according to claim 8, further comprising a guide along the adjacent holes.

11. The pin arrangement array body according to claim 8, wherein depths of the holes vary depending on positions where the holes are provided.

12. The pin arrangement array body according to claim 8, wherein the pin arrangement array body constitutes a part of a substrate on which a plurality of electronic devices is mounted.

13. (canceled)

14. A pin arrangement method comprising:
arranging a plurality of pins having a diameter and a length of micro sizes and responsive to a magnetic field on a pin arrangement array body having holes of a diameter and a length corresponding to the diameter and length of the pins; and
inserting the pins into the holes of the pin arrangement array body by applying a magnetic field to the pin arrangement array body in addition to swinging and vibrating in a vertical direction or a horizontal direction the pin arrangement array body.
